(19) United States
(12) Patent Application Publication
(10) Pub. No.: US 2019/0044086 A1
(43) Pub. Date: Feb. 7, 2019

(54) ORGANIC ELECTROLUMINESCENT DEVICE AND DISPLAY PANEL

(71) Applicant: Wuhan China Star Optoelectronics Semiconductor Display Technology Co., Ltd., Wuhan, Hubei (CN)

(72) Inventor: Cunjun XIA, Shenzhen, Guangdong (CN)

(73) Assignee: Wuhan China Star Optoelectronics Semiconductor Dis play Technology Co., Ltd., Wuhan, Hubei (CN)

(21) Appl. No.: 15/561,064

(22) PCT Filed: Sep. 21, 2017
(86) PCT No.: PCT/CN2017/102578

§ 371 Date: Sep. 24, 2017

(30) Foreign Application Priority Data
Aug. 1, 2017 (CN) 201710649460.0

(51) Int. Cl. H01L 51/50; G09G 3/3208; H01L 51/52; H01L 27/32

(52) U.S. Cl. CPC H01L 51/5064; H01L 51/508; H01L 51/5092; H01L 27/3211; G09G 3/3208; H01L 51/5215; H01L 51/5012

(57) ABSTRACT

The present invention discloses an organic electroluminescent device and a display panel. The organic electroluminescent device comprises a first anode, a first hole-injection layer, a first hole-transport layer, a first organic light-emitting layer, a first electron-transport layer, a first electron-injection layer, a charge-generation layer, a second electron-injection layer, a second electron-transport layer, a second organic light-emitting layer, a second hole-transport layer, a second hole-injection layer, and a second anode stacked sequentially. The invention can reduce difficulty of forming display panel, improve pixel resolution, improve product yield rate, and save cost.

### FIELD OF THE DISCLOSURE

Aspects of the present invention relate to display panel technology field, especially related to an organic electroluminescent device and a display panel.

### BACKGROUND

Compared with the liquid crystal display panel, OLED (Organic Light-Emitting Diode) display panel has the advantages of low energy consumption, low production cost, self-luminous, wide viewing angle and fast response. With the OLED display color, high resolution and large area, it requires more stringent about the fine metal mask size and positioning accuracy.

To improve pixel resolution, the compressing pixels space is used. However it is very difficult, more costs, and lower yield rate; moreover, the preparation of manufacturing with five FMM (Fine Metal Mask) will encounter low yield, high preparation costs and other issues.

### SUMMARY

The present invention discloses an organic electroluminescent device and a display panel to reduce the difficulty of full color panel, improve pixel resolution and product yield, and save cost.

In order to achieve the above object, an embodiment of the present invention provides an organic electroluminescent device, comprising a first anode, a first hole-injection layer, a first hole-transport layer, a first organic light-emitting layer, a first electron-transport layer, a first electron-injection layer, a charge-generation layer, a second electron-injection layer, a second electron-transport layer, a second organic light-emitting layer, a second hole-transport layer, a second hole-injection layer, and a second anode stacked sequentially.

In order to achieve the above object, another embodiment of the present invention provides a display panel, comprising a substrate, a driving circuit, and a plurality of organic electroluminescent devices disposed on the substrate; wherein the driving circuit coupled to the organic electroluminescent device for controlling light-emitting of the first organic light emitting layer and the second organic light emitting layer of the organic electroluminescent device.

The advantages of the present invention, in contrast to the prior art, is that the invention adds an inductive OLED device structure to a positive OLED device structure and adds a layer of charge generation layer between the two OLEDs, so the organic electroluminescent device comprises two light emitting layers; wherein the second organic light-emitting layer is a first primary-color light-emitting layer, the first organic light-emitting layer is a second primary-color light-emitting layer or a third primary-color light-emitting layer, so the space required for displaying the three primary colors is reduced, and the pixel resolution is increased; wherein second organic light-emitting layer is the first primary color light-emitting layer, so it is not necessary to use the FMM in the production of the second organic light-emitting layer; on the contrary, a conventional mask plate could meet the requirements, reduce the difficulty of preparing the display panel, improve the product yield and save cost.

### BRIEF DESCRIPTION OF THE DRAWINGS

FIG. 1 is a schematic diagram of an embodiment of an organic electroluminescent device of the present invention;

FIG. 2 is a schematic structural diagram of an embodiment of a display panel of the present invention;

FIG. 3 is a schematic structural diagram of the first embodiment of the organic electroluminescent device on the display panel of the present invention; and

FIG. 4 is a schematic structural diagram of the second embodiment of the organic electroluminescent device on the display panel of the present invention.

### DETAILED DESCRIPTION OF PREFERRED EMBODIMENTS

The embodiments are described below in order to explain the present invention by referring to the figures. In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. All other embodiments obtained by those of ordinary skill in the art without making creative work are within the scope of this application, based on the embodiments of the present application.

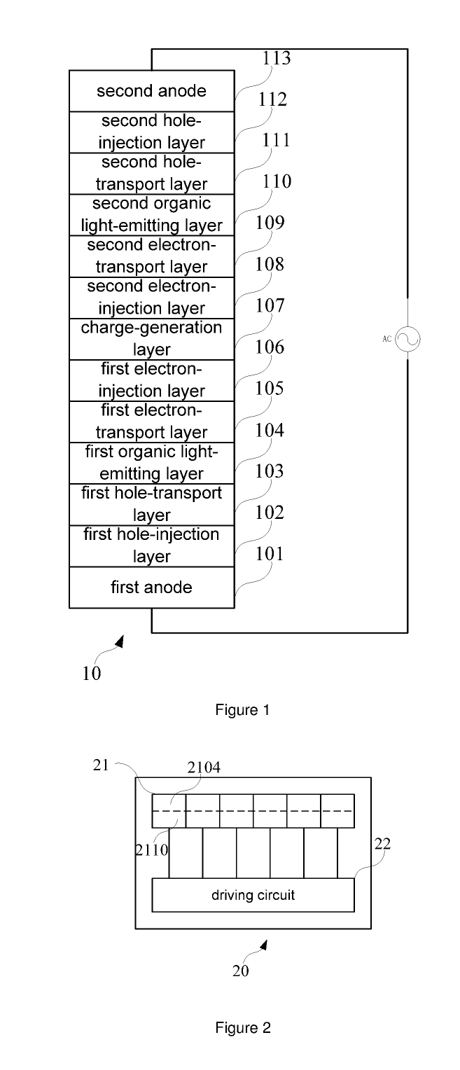

Referring to FIG. 1, the schematic diagram of an embodiment of an organic electroluminescent device of the present invention, an organic electroluminescent device 10 comprises a first anode 101, a first hole-injection layer 102, a first hole-transport layer 103, a first organic light-emitting layer 104, a first electron-transport layer 105, a first electron-injection layer 106, a charge-generation layer 107, a second electron-injection layer 108, a second electron-transport layer 109, a second organic light-emitting layer 110, a second hole-transport layer 111, a second hole-injection layer 112, and a second anode 113, stacked sequentially.

In the present embodiment, the second anode 113 is transparent material, so that the light emitted from the first organic light-emitting layer 104 and the second organic light-emitting layer 110 can be transmitted. In other embodiments, the first anode 101 is a transparent material, or both the first anode 101 and the second anode 113 are both transparent materials.

The second organic light-emitting layer 110 is a first primary-color light-emitting layer, the first organic light-emitting layer 104 is a second primary-color light-emitting layer or a third primary-color light-emitting layer. In the present embodiment, the first primary color light is blue light, the second primary color light is red light, and the third primary color light is green light; in other words, the second organic light emitting layer 110 is a blue light emitting layer, and the first organic light emitting layer 104 is a red light or a green light emitting layer. The reason of above arrangement is that the lifetime of the blue light emitting layer is shorter than that of the red light emitting layer or the green light emitting layer; therefore, the light-loss of the red light emitting layer or the green light emitting layer disposed on the first organic light emitting layer 104 and transmitting to the second anode 113 is greater than the light-loss of the blue light emitting layer disposed on the first organic light emitting layer 104 and transmitting to the second anode 113; thus, to emit stronger lights, the power ratio of the red light emitting layer or the green light emitting layer on the first organic light emitting layer 104 must larger than the power ratio of the blue light emitting layer on the second organic light emitting layer 110, so that the light intensity is equal regardless of the color of the light transmits out of the second anode 113; hence, disposing blue light emitting layer which has a shorter life on the second organic light emitting layer 110, can effectively reduce the loss of blue light-emitting layer and extend the life of organic electroluminescent devices.

It is to be understood that this embodiment only lists the primary color distribution pattern of the two-layer organic light-emitting layer in consideration of the primary color light lifetime. In other embodiments, the first organic light emitting layer 104 and the second organic light emitting layer 110 may be any combination of light emitting layers of three primary colors; for example, the first organic light emitting layer 104 is a red light emitting layer, and the second organic light emitting layer 110 is a green light emitting layer or a blue light emitting layer; or the first organic light emitting layer 104 is a green light emitting layer, and the second organic light emitting layer 110 is a red light emitting layer or a blue light emitting layer.

In the production process of the present embodiment, the first hole-injection layer 102 disposed on the surface of the first anode 101 by evaporating with a first mask plate; the first hole-transport layer 103 disposed on the surface of the first hole-injection layer 102 by evaporating with the first mask plate; the first organic light-emitting layer 104 disposed on the surface of the first hole-transport layer 102 by evaporating with a first explicit mask plate when the first organic light-emitting layer 104 is a red light-emitting layer; and the first organic light-emitting layer 104 disposed on the surface of the first hole-transport layer 102 by evaporating with a second explicit mask plate when the first organic light-emitting layer 104 is a green light-emitting layer; wherein the first electron-transport layer 105, the first electron-injection layer 106, the charge generation layer 107, the second electron-injection layer 108, the second electron-transport layer 109, the second organic light-emitting layer 110, the second hole-transport layer 111, and the second hole-injection layer 112 deposed sequentially by evaporating with the first mask plate; the second anode 113 disposed on the surface of the second hole-injection layer 112 by evaporating with a second mask plate.

Since the second organic light emitting layer 110, the first hole injection layer 102, the first hole transport layer 103, the first electron transport layer 105, the first electron injection layer 106, the charge generation layer 107, the second electron injection layer 108, The second electron transport layer 109, the second hole transport layer 111, and the second hole injection layer 112 are all distributed on the display panel with full-face distributions, it merely requires general masks to complete the manufacture without precision masks; on the contrary, the first organic light-emitting layer 104 needs to be distinguished from the green light-emitting layer or the green light-emitting layer in the manufacturing, and the red light emitting layer and the green light emitting layer are different in position, so the first explicit mask plate is required in the manufacturing of the red light emitting layer and the second explicit mask plate is required in the manufacturing of the green light emitting layer. Moreover, the second anode 113 is also a full-face distribution, so it requires merely a conventional mask plate, but the second anode 113 needs to overlap the surrounding lead and therefore does not coincide with the mask used by the other layers.

In other embodiments, the functional layer of the organic electroluminescent device of the present embodiment may be formed by other processes, and is not limited thereto.

For the driving mode of the organic electroluminescent device of the present embodiment, since the charge generation layer is located in the middle, the organic electroluminescent device corresponds to two light-emitting diodes connected to the two negative electrodes, the DC current cannot pass through, and the organic electroluminescent device cannot emit light; therefore, the present embodiment requires an AC power source to drive lights.

As described above, in the present embodiment, by connecting two OLED light emitting devices on both ends of the charge generation layer and providing two light emitting layers in one organic electroluminescent device, the space required for displaying the three primary colors can be effectively reduced; entire manufacturing process only requires the use of two precision mask panels so minimizes the difficulty of preparation of the display panel, improves product yield and saves cost.

Referring to FIG. 2, schematic structural diagram of an embodiment of a display panel of the present invention, the display panel 20 comprises a plurality of organic electroluminescent devices 21, a driving circuit 22 and a substrate 23 as shown in FIG. 1. The driving circuit 22 is coupled to the organic electroluminescent device 21, and the organic electroluminescent device 21 comprises a first organic light emitting layer 2104 and a second organic light emitting layer 2110 (not shown on other layers, may refer to the FIG. 1). As described in the example, the organic electroluminescent device 21 requires an AC power source to be driven, and the drive circuit 22 can provide high frequency alternating current at a frequency of 100 Hz to 1 MHz. When the driving circuit 22 supplies a complete pulse signal, both the first organic light emitting layer 2104 and the second organic light emitting layer 2110 emit light. The driving circuit 22 comprises a filter circuit (not shown) for filtering the pulse signal outputted from the driving circuit 22, so the pulse signal outputted from the driving circuit 22 is a forward pulse signal or a reverse pulse signal. The first organic light emitting layer 2104 emits light when the drive circuit 22 provides a forward pulse signal, and the second organic light emitting layer 2110 emits light when the drive circuit 22 provides a reverse pulse signal.

As above description, the present embodiment satisfies different display requirements by controlling the emitting respectively, or simultaneously of the organic light-emitting layer and the second organic light-emitting layer of the organic electroluminescent device with the different pulse signals provided from the driving circuit.

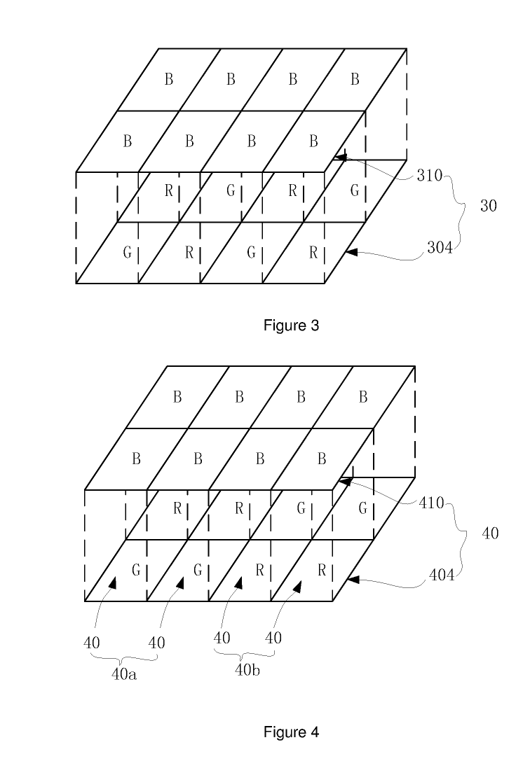

Referring to FIG. 3, the schematic structural diagram of the first embodiment of the organic electroluminescent device on the display panel of the present invention, in order to clearly show the settings, this figure merely shows the first organic light emitting layer 304 and the second organic light emitting layer 310 of the organic electroluminescent device 30 of the present invention. The organic electroluminescent device of which the first organic light-emitting layer is the second primary-color light-emitting layer and the organic electroluminescent device of which the first organic light-emitting layer is the third primary-color light-emitting layer are disposed separately on the substrate. In the present embodiment, the first primary color is blue B, the second primary color is red R, the third primary color is green G, so, as shown in FIG. 3, the organic electroluminescent device of which the first organic light-emitting layer is the red light-emitting layer and the organic electroluminescent device of which the first organic light-emitting layer is the green light-emitting layer are disposed separately on the substrate. The second organic light emitting layers are all blue light emitting layers; since the life of the blue light emitting layer is shorter than life of the red light emitting layer and the green light emitting layer, the entire surface of the blue light emitting layer is disposed at a position close to the transparent second anode to reduce the loss of the light emitted from the blue light emitting layer; moreover, since the second organic light emitting layer is blue, the power of the blue light emitting layer of a single organic electroluminescent device is relatively low, and that shall contribute to extending the life of the organic electroluminescent device and the display panel.

In other embodiments, the organic electroluminescent device of which the first organic light-emitting layer is the blue light-emitting layer and the organic electroluminescent device of which the first organic light-emitting layer is the green light-emitting layer are disposed separately on the substrate, or the organic electroluminescent device of which the first organic light-emitting layer is the red light-emitting layer and the organic electroluminescent device of which the first organic light-emitting layer is the red light-emitting layer are disposed separately on the substrate.

As above description, the embodiment of present invention effectively extends the life of organic electroluminescent devices and display panels, reduces the display of three primary colors required space, improves the pixel resolution by at least two arrangements: the organic electroluminescent device of which the first organic light-emitting layer is the blue light-emitting layer and the organic electroluminescent device of which the first organic light-emitting layer is the green light-emitting layer are disposed separately on the substrate, or the organic electroluminescent device of which the first organic light-emitting layer is the red light-emitting layer and the organic electroluminescent device of which the first organic light-emitting layer is the red light-emitting layer are disposed separately on the substrate.

Referring to FIG. 4, the schematic structural diagram of the second embodiment of the organic electroluminescent device on the display panel of the present invention, in order to clearly show the settings, the FIG. 4, merely discloses the first organic light emitting layer 404 and the second organic light emitting layer 410 of the organic electroluminescent device 40 of the present invention. A first organic electroluminescent device set 40b comprise a plurality of the organic electroluminescent devices 404 of which the first organic light-emitting layers 40 are the second primary-color light-emitting layers, a second organic electroluminescent device set 40a comprise a plurality of the organic electroluminescent devices 404 of which the first organic light-emitting layers 40 are the third primary-color light-emitting layers, and the first organic electroluminescent device set and the second organic electroluminescent device set are disposed separately on the substrate. In the present embodiment, the first primary color is blue B, the second primary color is red R, the third primary color is green G, so, as shown in FIG. 4, a first organic electroluminescent device set comprise two organic electroluminescent devices of which the first organic light-emitting layers are red light-emitting layers, a second organic electroluminescent device set comprise two organic electroluminescent devices of which the first organic light-emitting layers are green light-emitting layers, and the first organic electroluminescent device set and the second organic electroluminescent device set are disposed separately on the substrate.

In other embodiments, the organic electroluminescent device group may also be composed of three, four or more first organic light emitting layers which are red or green organic electroluminescent devices, and the amount of organic electroluminescent devices included in the first organic electroluminescent device group is not necessarily equal to the amount of organic electroluminescent devices included in the second organic electroluminescent device group, so, by adjusting the brightness of the first organic light emitting layer, the light emitted by the first organic electroluminescent device group and the second organic electroluminescent device group can be combined with the light of the desired color and the light intensity required to reach the desired light intensity.

As above description, the present embodiment can reduce the difficulty of production, improve the yield and reduce the production cost by forming the organic electroluminescent device group by combining the organic electroluminescent devices in which the plurality of first organic light emitting layers are uniform in color.

In contrast to the prior art, the present invention reducing the space for displaying the three primary colors and increasing the pixel resolution by using a charge generation layer to connect two mutually opposed OLED devices through a charge generation layer, so the organic electroluminescent device comprises two light emitting layers, the second organic light-emitting layer is a first primary-color light-emitting layer, and the first organic light-emitting layer is a second primary-color light-emitting layer or a third primary-color light-emitting layer; the present invention also satisfies different display requirements by controlling the emitting respectively, or simultaneously of the organic light-emitting layer and the second organic light-emitting layer of the organic electroluminescent device with the different pulse signals provided from the driving circuit; in the manufacturing process, the present invention reduce the use of precision mask plate times, reduce the difficulty of preparing the display panel, improve product yield, and save cost as well.

Although a few embodiments of the present invention have been shown and described, it would be appreciated by those skilled in the art that changes may be made in this embodiment without departing from the principles and spirit of the invention, the scope of which is defined in the claims and their equivalents.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claim is:

1. An organic electroluminescent device, comprising:
a first anode, a first hole-injection layer, a first hole-transport layer, a first organic light-emitting layer, a first electron-transport layer, a first electron-injection layer, a charge-generation layer, a second electron-injection layer, a second electron-transport layer, a second organic light-emitting layer, a second hole-transport layer, a second hole-injection layer, and a second anode stacked sequentially; wherein the second organic light-emitting layer is a first primary-color light-emitting layer, the first organic light-emitting layer is a second primary-color light-emitting layer or a third primary-color light-emitting layer; wherein the first hole-injection layer disposed on the surface of the first anode by evaporating with a first mask plate; wherein the first hole-transport layer disposed on the surface of the first hole-injection layer by evaporating with the first mask plate; and wherein the first electron-transport layer, the first electron-injection layer, the charge generation layer, the second electron-injection layer, the second electron-transport layer, the second organic light-emitting layer, the second hole-transport layer, and the second hole-injection layer deposed sequentially by evaporating with the first mask plate.

2. The organic electroluminescent device of claim 1, wherein the first primary-color is blue, the second primary-color is red, and third primary-color is green.

3. The organic electroluminescent device of claim 2, wherein the first organic light-emitting layer disposed on the surface of the first hole-transport layer by evaporating with a first explicit mask plate when the first organic light-emitting layer is a red light-emitting layer; and the first organic light-emitting layer disposed on the surface of the first hole-transport layer by evaporating with a second explicit mask plate when the first organic light-emitting layer is a green light-emitting layer.

4. The organic electroluminescent device of claim 1, wherein the second anode disposed on the surface of the second hole-injection layer by evaporating with a second mask plate.

5. An organic electroluminescent device, comprising:
a first anode, a first hole-injection layer, a first hole-transport layer, a first organic light-emitting layer, a first electron-transport layer, a first electron-injection layer, a charge-generation layer, a second electron-injection layer, a second electron-transport layer, a second organic light-emitting layer, a second hole-transport layer, a second hole-injection layer, and a second anode stacked sequentially; and wherein the second organic light-emitting layer is a first primary-color light-emitting layer, the first organic light-emitting layer is a second primary-color light-emitting layer or a third primary-color light-emitting layer.

6. The organic electroluminescent device of claim 5, wherein the first hole-injection layer disposed on the surface of the first anode by evaporating with a first mask plate; and wherein the first hole-transport layer disposed on the surface of the first hole-injection layer by evaporating with the first mask plate.

7. The organic electroluminescent device of claim 5, wherein the first primary-color is blue, the second primary-color is red, and third primary-color is green.

8. The organic electroluminescent device of claim 7, wherein the first organic light-emitting layer disposed on the surface of the first hole-transport layer by evaporating with a first explicit mask plate when the first organic light-emitting layer is a red light-emitting layer; and the first organic light-emitting layer disposed on the surface of the first hole-transport layer by evaporating with a second explicit mask plate when the first organic light-emitting layer is a green light-emitting layer.

9. The organic electroluminescent device of claim 5, wherein the first electron-transport layer, the first electron-injection layer, the charge generation layer, the second electron-injection layer, the second electron-transport layer, the second organic light-emitting layer, the second hole-transport layer, and the second hole-injection layer deposed sequentially by evaporating with the first mask plate.

10. The organic electroluminescent device of claim 5, wherein the second anode disposed on the surface of the second hole-injection layer by evaporating with a second mask plate.

11. The organic electroluminescent device of claim 5, wherein the second anode used transparent material; the organic electroluminescent device driven by a AC power.

12. A display panel, comprising a substrate, a driving circuit, and a plurality of organic electroluminescent devices disposed on the substrate; wherein the electroluminescent device comprising:
a first anode, a first hole-injection layer, a first hole-transport layer, a first organic light-emitting layer, a first electron-transport layer, a first electron-injection layer, a charge-generation layer, a second electron-injection layer, a second electron-transport layer, a second organic light-emitting layer, a second hole-transport layer, a second hole-injection layer, and a second anode stacked sequentially; wherein the second organic light-emitting layer is a first primary-color light-emitting layer, the first organic light-emitting layer is a second primary-color light-emitting layer or a third primary-color light-emitting layer; and wherein the driving circuit coupled to the organic electroluminescent device for controlling light-emitting of the first organic light emitting layer and the second organic light emitting layer of the organic electroluminescent device.

13. The display panel of claim 12, wherein the first hole-injection layer disposed on the surface of the first anode by evaporating with a first mask plate; and wherein the first hole-transport layer disposed on the surface of the first hole-injection layer by evaporating with the first mask plate.

14. The display panel of claim 12, wherein the first primary-color is blue, the second primary-color is red, and third primary-color is green.

15. The display panel of claim 14, wherein the first organic light-emitting layer disposed on the surface of the first hole-transport layer by evaporating with a first explicit mask plate when the first organic light-emitting layer is a red light-emitting layer; and the first organic light-emitting layer disposed on the surface of the first hole-transport layer by evaporating with a second explicit mask plate when the first organic light-emitting layer is a green light-emitting layer.

16. The display panel of claim 12, wherein the first electron-transport layer, the first electron-injection layer, the charge generation layer, the second electron-injection layer, the second electron-transport layer, the second organic light-emitting layer, the second hole-transport layer, and the second hole-injection layer deposed sequentially by evaporating with the first mask plate.

17. The display panel of claim 12, wherein the second anode disposed on the surface of the second hole-injection layer by evaporating with a second mask plate.

18. The display panel of claim 12, wherein the second anode used a transparent material; the organic electroluminescent device driven by AC power.

19. The display panel of claim 12, wherein the organic electroluminescent device of which the first organic light-emitting layer is the second primary-color light-emitting layer and the organic electroluminescent device of which the first organic light-emitting layer is the third primary-color light-emitting layer are disposed separately on the substrate.

20. The display panel of claim 12, further comprising:
a first organic electroluminescent device set comprise a plurality of the organic electroluminescent devices of which the first organic light-emitting layers are the second primary-color light-emitting layers;
a second organic electroluminescent device set comprise a plurality of the organic electroluminescent devices of which the first organic light-emitting layers are the third primary-color light-emitting layers;
wherein the first organic electroluminescent device set and the second organic electroluminescent device set are disposed separately on the substrate.
